(19) United States
(12) Patent Application Publication
(10) Pub. No.: US 2022/0285126 A1
(43) Pub. Date: Sep. 8, 2022

(54) ION IMPLANTER AND ION IMPLANTATION METHOD

(71) Applicant: SUMITOMO HEAVY INDUSTRIES ION TECHNOLOGY CO., LTD., Tokyo (JP)

(72) Inventor: Mitsukuni Tsukihara, Ehime (JP)

(21) Appl. No.: 17/684,846

(22) Filed: Mar. 2, 2022

(30) Foreign Application Priority Data
Mar. 4, 2021 (JP) 2021-034380

(51) Int. Cl. H01J 37/30; H01J 37/317; C23C 14/48

(52) U.S. Cl. CPC H01J 37/3007; H01J 37/3171; C23C 14/48

(57) ABSTRACT

Provided is an ion implanter including an ion source that generates ions, an extraction unit that generates an ion beam by extracting the ions from the ion source and accelerating the ions, a linear acceleration unit that accelerates the ion beam extracted and accelerated by the extraction unit, an electrostatic acceleration/deceleration unit that accelerates or decelerates the ion beam emitted from the linear acceleration unit, and an implantation processing chamber in which implantation process is performed by irradiating a workpiece with the ion beam emitted from the electrostatic acceleration/deceleration unit.

### RELATED APPLICATIONS

The content of Japanese Patent Application No. 2021-034380, on the basis of which priority benefits are claimed in an accompanying application data sheet, is in its entirety incorporated herein by reference.

### BACKGROUND

### Technical Field

Certain embodiments of the present invention relate to an ion implanter and an ion implantation method.

### Description of Related Art

In a semiconductor manufacturing process, a process of implanting ions into a semiconductor wafer (also referred to as an ion implantation process) is generally performed in order to change conductivity of a semiconductor, or in order to change a crystal structure of the semiconductor. A device used for the ion implantation process is called an ion implanter. Implantation energy of the ions is determined depending on a desired implantation depth of the ions implanted near a surface of the wafer. A high energy (for example, 1 MeV or higher) ion beam is used for implantation into a relatively deep region.

In the ion implanter capable of outputting the high energy ion beam, the ion beam is accelerated by using a multi-stage high frequency linear acceleration unit (LINAC). In the high frequency linear acceleration unit, high frequency parameters such as a voltage amplitude, a frequency, and a phase in each stage are adjusted to obtain desired beam energy.

### SUMMARY

According to an embodiment of the present invention, there is provided an ion implanter comprising:
an ion source that generates ions, an extraction unit that generates an ion beam by extracting the ions from the ion source and accelerating the ions, a linear acceleration unit that accelerates the ion beam extracted and accelerated by the extraction unit, an electrostatic acceleration/deceleration unit that accelerates or decelerates the ion beam emitted from the linear acceleration unit, and an implantation processing chamber in which an implantation process is performed by irradiating a workpiece with the ion beam emitted from the electrostatic acceleration/deceleration unit.

According to another embodiment of the present invention, there is provided an ion implantation method. The ion implantation method includes causing a linear acceleration unit to accelerate an ion beam, causing an electrostatic acceleration/deceleration unit to accelerate or decelerate the ion beam emitted from the linear acceleration unit, and irradiating a workpiece with the ion beam emitted from the electrostatic acceleration/deceleration unit.

### BRIEF DESCRIPTION OF THE DRAWINGS

FIG. 1 is a top view illustrating a schematic configuration of an ion implanter according to an embodiment.

FIG. 2 is a view schematically illustrating an energy adjustment method for a plurality of ion beams having mutually different beam energy used for multiple implantation.

FIG. 3 is a flowchart illustrating an example of a first adjustment method for an ion beam.

FIG. 4 is a flowchart illustrating an example of a second adjustment method for the ion beam.

FIG. 5 is a top view illustrating a schematic configuration of an ion implanter according to a modification example.

FIG. 6 is a top view illustrating a schematic configuration of an ion implanter according to another modification example.

### DETAILED DESCRIPTION

Recently, an ultra-high energy (for example, 4 MeV or higher) ion beam may be required for implantation into a deeper region. In order to enable the ultra-high energy ion beam to be output, it is necessary to increase the number of stages of the high frequency linear acceleration unit, compared to that in the related art. As the number of stages of the high frequency linear acceleration unit increases, a time required for adjusting the high frequency parameters is lengthened accordingly. Depending on semiconductor manufacturing processes, in some cases, it may be necessary to perform multiple implantation for irradiating the same wafer with a plurality of ion beams having mutually different beam energy. In this case, a plurality of data sets corresponding to a plurality of the beam energy have to be generated. As a result, a time required for adjusting the high frequency parameter is further lengthened, thereby leading to degraded productivity of the ion implanter.

It is desirable to provide a technique for more quickly adjusting beam energy in an ion implanter including a linear acceleration unit.

Any desired combination of the above-described components, and those in which the components or expressions according to the present invention are substituted from each other in methods, devices, or systems are effectively applicable as an aspect of the present invention.

According to an aspect of the present invention, beam energy can more quickly be adjusted, and an ion implantation process using an ion beam having various types of beam energy can easily be realized.

Hereinafter, embodiments according to the present invention will be described in detail with reference to the drawings. In describing the drawings, the same reference numerals will be assigned to the same elements, and repeated description will appropriately be omitted. Configurations described below are merely examples, and do not limit the scope of the present invention in any way.

Before the embodiments are described in detail, an outline will be described. The present embodiment relates to an ion implanter for high energy ion beam. The ion implanter causes a high frequency linear acceleration unit to accelerate an ion beam generated by an ion source, transports a high energy ion beam obtained by the acceleration to a workpiece (for example, a substrate or a wafer) along a beamline, and implants ions into the workpiece. In the following description, in order to facilitate understanding, an example will be described on the premise that the “workpiece (for example, the substrate or the wafer)” is the “wafer”. However, the ion implantation method and the ion implanter according to the present disclosure is not limited to the example. For example, a specific example of the “workpiece (for example, the substrate or the wafer)” includes not only a semiconductor wafer but also a flat panel display substrate (for example, a glass substrate).

The term “high energy” in the present embodiment means beam energy of 1 MeV or higher, 4 MeV or higher, or 10 MeV or higher. According to high energy ion implantation, desired dopant ions are implanted into a wafer surface with relatively high energy. Therefore, the desired dopant ions can be implanted into a deeper region (for example, a depth of 5 μm or larger) of the wafer surface. For example, an application field of the high energy ion implantation is to form a P-type region and/or an N-type region in manufacturing a semiconductor device such as a state-of-the-art image sensor.

In order to realize a desired beam condition in the ion implanter, it is necessary to properly set operation parameters of various devices constituting the ion implanter. In order to obtain the ion beam having desired beam energy, it is necessary to properly set operation parameters of high frequency accelerators respectively in a plurality of stages. In addition, there are lens devices for properly transporting the ion beam on an upstream side and a downstream side of the high frequency accelerator in each stage. In order to obtain the ion beam having a desired beam current, it is necessary to properly set operation parameters of the lens devices respectively in a plurality of stages. Furthermore, in order to adjust beam quality such as parallelism and angle distribution of the ion beam with which the wafer is irradiated, it is necessary to properly set operation parameters of various devices on a downstream side of the linear acceleration unit. A set of the operation parameters is generated as a “data set” for achieving the desired beam condition.

In order to generate a higher energy ion beam, it is necessary to provide the linear acceleration unit having a larger number of stages of the high frequency accelerators. When the number of stages of the high frequency accelerators increases, the number of operation parameters to be adjusted also increases. Accordingly, a time required for generating a proper data set is lengthened. Depending on the semiconductor manufacturing process, it may be necessary to perform multiple implantation for irradiating the same wafer with a plurality of ion beams having mutually different beam energy. In this case, a plurality of data sets corresponding to the plurality of beam energy have to be generated. When the plurality of data sets are generated from scratch, it takes a very long time to generate all of the plurality of data sets. This case may lead to degraded productivity of the ion implanter.

In the present embodiment, an auxiliary electrostatic acceleration/deceleration unit is provided in a subsequent stage of the linear acceleration unit. The ion implanter according to the present embodiment includes an ion source that generates ions, an extraction unit that generates an ion beam by extracting the ions from the ion source and accelerating the ions, a linear acceleration unit that accelerates the ion beam extracted and accelerated by the extraction unit, an electrostatic acceleration/deceleration unit that accelerates or decelerates the ion beam emitted from the linear extraction unit, and an implantation processing chamber in which an implantation process is performed by irradiating a wafer with the ion beam emitted from the electrostatic acceleration/deceleration unit. According to the present embodiment, the electrostatic acceleration/deceleration unit is provided in the subsequent stage of the linear acceleration unit. In this manner, the beam energy of the ion beam with which the wafer is irradiated can be adjusted within a prescribed range while the operation parameters of the linear acceleration unit are fixed.

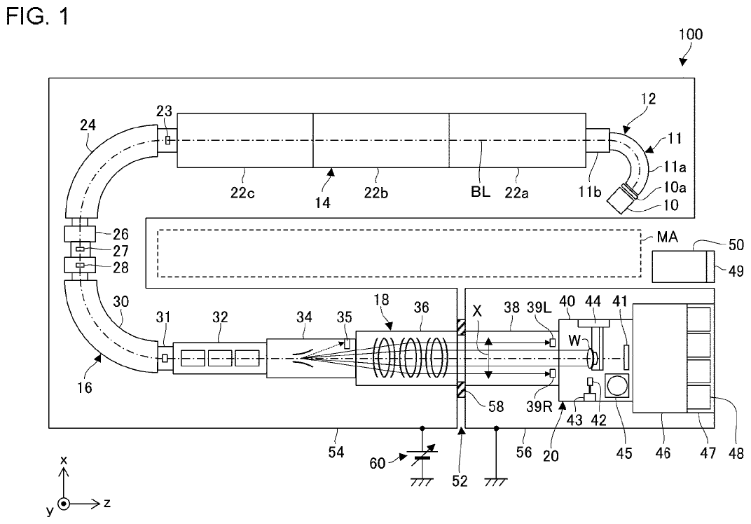

FIG. 1 is a top view schematically illustrating an ion implanter 100 according to an embodiment. The ion implanter 100 includes a beam generation unit 12, a beam acceleration unit 14, a beam deflection unit 16, a beam transport unit 18, and a substrate transferring/processing unit 20.

The beam generation unit 12 has an ion source 10 and a mass analyzer 11. In the beam generation unit 12, the ions generated by the ion source 10 are extracted by the extraction unit 10a. The extraction unit 10a extracts the ions from the ion source 10, and accelerates the ions, thereby generating the ion beam. The ion beam extracted by the extraction unit 10a is subjected to mass analysis by the mass analyzer 11. The mass analyzer 11 has a mass analyzing magnet 11a and a mass resolving slit 11b. The mass resolving slit 11b is disposed on a downstream side of the mass analyzing magnet 11a. As a result of the mass analysis performed by the mass analyzer 11, only an ion species required for implantation is selected, and the ion beam of the selected ion species is guided to the subsequent beam acceleration unit 14.

The beam acceleration unit 14 has a plurality of linear acceleration units 22a, 22b, and 22c for accelerating the ion beam and a beam measurement unit 23, and forms a linearly extending portion of a beamline BL. Each of the plurality of linear acceleration units 22a to 22c includes one or more high frequency accelerators respectively in one or more stages, and causes a radio frequency (RF) electric field to act on and accelerate the ion beam. The beam measurement unit 23 is provided most downstream of the beam acceleration unit 14, and measures at least one beam characteristic of a high energy ion beam accelerated by the plurality of linear acceleration units 22a to 22c. The beam measurement unit 23 may be a measurement device that measures the beam characteristic such as beam energy, a beam current, a beam profile, or the like.

In the present embodiment, three linear acceleration units 22a to 22c are provided. The first linear acceleration unit 22a is provided in an upper stage of the beam acceleration unit 14, and includes the high frequency accelerators respectively in a plurality of stages (for example, 5 to 15 stages). The first linear acceleration unit 22a performs “bunching” of a continuous beam (DC beam) emitted from the beam generation unit 12 to match a specific acceleration phase, and accelerates the ion beam to have the energy of approximately 1 MeV, for example. The second linear acceleration unit 22b is provided in a middle stage of the beam acceleration unit 14, and includes the high frequency accelerators respectively in a plurality of stages (for example, 5 to 15 stages). The second linear acceleration unit 22b accelerates the ion beam emitted from the first linear acceleration unit 22a to have the energy of approximately 2 to 3 MeV, for example. The third linear acceleration unit 22c is provided in the lower stage of the beam acceleration unit 14, and includes a high frequency accelerators respectively in a plurality of stages (for example, 5 to 15 stages). The third linear acceleration unit 22c accelerates the ion beam emitted from the second linear acceleration unit 22b to have the high energy of 4 MeV or higher, for example.

The high energy ion beam emitted from the beam acceleration unit 14 has an energy distribution in a certain range. Therefore, in order that the high energy ion beam is scanned and parallelized downstream of the beam acceleration unit 14 to irradiate the wafer, highly accurate energy analysis, energy distribution control, trajectory correction, and beam convergence/divergence adjustment need to be performed in advance.

The beam deflection unit 16 performs energy analysis, energy distribution control, and trajectory correction of the high energy ion beam emitted from the beam acceleration unit 14. The beam deflection unit 16 forms a portion extending in an arc shape in the beamline BL. A direction of the high energy ion beam is changed toward the beam transport unit 18 by the beam deflection unit 16.

The beam deflection unit 16 includes an energy analysis electromagnet 24, a horizontally focusing quadrupole lens 26 that suppresses energy dispersion, an energy resolving slit 27, a first Faraday cup 28, a bending electromagnet 30 that provides beam steering (trajectory correction), and a second Faraday cup 31. The energy analysis electromagnet 24 is referred to as an energy filter electromagnet (EFM). In addition, a device group including the energy analysis electromagnet 24, the horizontally focusing quadrupole lens 26, the energy resolving slit 27, and the first Faraday cup 28 is collectively referred to as an “energy analysis device”.

The energy resolving slit 27 may be configured so that a slit width is variable to adjust resolution of the energy analysis. For example, the energy resolving slit 27 may be configured to include two blocking bodies that are movable in a slit width direction, and may be configured so that the slit width is adjustable by changing an interval between the two blocking bodies. The energy resolving slit 27 may be configured so that the slit width is variable by selecting any one of a plurality of slits having different slit widths.

The first Faraday cup 28 is disposed immediately after the energy resolving slit 27, and is used in measuring the beam current for the energy analysis. The second Faraday cup 31 is disposed immediately after the bending electromagnet 30, and is provided to measure the beam current of the ion beam which enters the beam transport unit 18 after beam trajectory correction. Each of the first Faraday cup 28 and the second Faraday cup 31 is configured to be movable into and out of the beamline BL by an operation of a Faraday cup drive unit (not illustrated). Each of the first Faraday cup 28 and the second Faraday cup 31 may be a measurement device that measures the beam characteristic such as the beam current or the beam profile.

The beam transport unit 18 forms the other linearly extending portion of the beamline BL, and is parallel to the beam acceleration unit 14 while a maintenance area MA in a center of the ion implanter 100 is interposed therebetween. A length of the beam transport unit 18 is designed to be approximately the same as a length of the beam acceleration unit 14. As a result, the beamline BL including the beam acceleration unit 14, the beam deflection unit 16, and the beam transport unit 18 forms a U-shaped layout as a whole. In the present specification, the beam transport unit 18 is also referred to as a “beamline unit”.

The beam transport unit 18 includes a beam shaper 32, a beam scanner 34, a beam dump 35, a beam parallelizer 36, a final energy filter 38, and left and right Faraday cups 39L and 39R.

The beam shaper 32 includes a focusing/defocusing lens such as a quadrupole lens device (Q lens), and is configured to shape the ion beam having passed through the beam deflection unit 16 into a desired cross-sectional shape. For example, the beam shaper 32 is configured to include an electric field type three-stage quadrupole lens (also referred to as a triplet Q lens), and has three electrostatic quadrupole lens devices. The beam shaper 32 can independently adjust convergence or divergence of the ion beam in each of a horizontal direction (x-direction) and a vertical direction (y-direction) by using the three lens devices. The beam shaper 32 may include a magnetic field type lens device, or may include a lens device that shapes the beam by using both an electric field and a magnetic field.

The beam scanner 34 is a beam deflection device configured to provide reciprocating scanning with the beam and to perform scanning in the x-direction with the shaped ion beam. The beam scanner 34 has a scanning electrode pair facing in a beam scanning direction (x-direction). The scanning electrode pair is connected to variable voltage power supplies (not illustrated), and a voltage applied between the scanning electrode pair is periodically changed. In this manner, an electric field generated between the electrodes is changed so that the ion beam is deflected at various angles. As a result, the scanning with the ion beam is performed over a scanning range indicated by an arrow X. In FIG. 1, a plurality of trajectories of the ion beam in the scanning range are indicated by fine solid lines. The beam scanner 34 may be replaced with another beam scan unit, and the beam scan unit may be configured to serve as an electromagnet device using the magnetic field.

The beam scanner 34 deflects the beam beyond the scanning range indicated by the arrow X. In this manner, the ion beam is incident into the beam dump 35 provided at a position away from the beamline BL. The beam scanner 34 temporarily retracts the ion beam from the beamline BL toward the beam dump 35, thereby blocking the ion beam so that the ion beam does not reach the substrate transferring/processing unit 20 located downstream.

The beam scanner 34 performs reciprocating scanning with the ion beam in a direction perpendicular to a beam traveling direction, thereby generating a ribbon-like beam flux that spreads in the x-direction, for example. Instead of the beam scanner 34, a ribbon beam generator that generates a ribbon beam by defocusing the ion beam in a direction perpendicular to the beam traveling direction may be provided. For example, the ribbon beam generator may be configured to include a magnetic field type or an electric field type beam defocusing device. In the present specification, the beam scanner 34 that generates the ribbon-like beam flux and the device that generates the ribbon beam are collectively referred to as the “ribbon beam generator”.

The beam parallelizer 36 is configured so that the traveling direction of the ion beam used for the scanning is parallel to a trajectory of the designed beamline BL. The beam parallelizer 36 has a plurality of arc-shaped parallelizing lens electrodes in a central portion of each of which a passing slit for the ion beam is provided. The parallelizing lens electrodes are connected to high-voltage power supplies (not illustrated), and applies the electric field generated by voltage application to the ion beam so that the traveling directions of the ion beam are parallelized. The beam parallelizer 36 may be replaced with another beam parallelizing device, and the beam parallelizing device may be configured to serve as an electromagnet device using the magnetic field. The beam parallelizer 36 may be configured to parallelize the traveling directions of the ribbon-like beam flux, or may be configured to parallelize the traveling directions of the ribbon beam.

The final energy filter 38 is an energy analyzer that analyzes the energy of the ion beam. The final energy filter 38 is configured to deflect the ions having the required energy downward (in the −y-direction) to be guided to the substrate transferring/processing unit 20. The final energy filter 38 is referred to as an angular energy filter(AEF). The final energy filter 38 has an AEF electrode pair for electric field deflection. The AEF electrode pair is connected to a high-voltage power supply (not illustrated). The ion beam is deflected downward by applying a positive voltage to an upper AEF electrode and applying a negative voltage to a lower AEF electrode. The final energy filter 38 may be configured to include an electromagnet device for magnetic field deflection, or may be configured to include a combination between the AEF electrode pair for electric field deflection and the electromagnet device for magnetic field deflection.

The final energy filter 38 further has an energy defining slit (not illustrated) provided downstream of the AEF electrode pair. The energy defining slit may be configured so that a slit width is variable to adjust resolution of the final energy filter 38. For example, the energy defining slit may be configured to include two blocking bodies that are movable in a slit width direction, and may be configured so that the slit width is adjustable by changing an interval between the two blocking bodies. The energy defining slit may change the slit width to be used to adjust the beam current of the ion beam with which the wafer W is irradiated.

The left and right Faraday cups 39L and 39R are provided downstream of the final energy filter 38, and are disposed at positions into which the left and right end beams in the scanning range indicated by the arrow X can be incident. The left and right Faraday cups 39L and 39R are provided at positions that do not block the beam toward the wafer W, and measure the beam current into the wafer W during ion implantation.

The substrate transferring/processing unit 20 is provided downstream of the beam transport unit 18, that is, on the most downstream side of the beamline BL. The substrate transferring/processing unit 20 includes an implantation processing chamber 40, a beam monitor 41, a beam profiler 42, a profiler driving device 43, a wafer holder 44, a wafer accommodation unit 45, a substrate transfer device 46, and a load port 47.

The beam monitor 41 is provided on the most downstream side of the beamline BL inside the implantation processing chamber 40. The beam monitor 41 is provided at a position into which the ion beam can be incident when the wafer W is not present on the beamline BL, and is configured to measure the beam characteristic before or between the ion implantation processes. The beam monitor 41 may be a measurement device that measures the beam characteristics such as the beam current, the beam current density distribution, the beam angle, and the beam parallelism. For example, the beam monitor 41 is located close to a transfer port (not illustrated) connecting the implantation processing chamber 40 and the substrate transfer device 46, and is provided at a position vertically below the transfer port.

The beam profiler 42 is configured to measure the beam current at a position on the surface of the wafer W. The beam profiler 42 is configured to be movable in the x-direction by an operation of the profiler driving device 43, is retracted from an implantation position where the wafer W is located during the ion implantation, and is inserted into the implantation position when the wafer W is not located at the implantation position. The beam profiler 42 measures the beam current while moving in the x-direction. In this manner, the beam profiler 42 can measure the beam current over the entire beam scanning range in the x-direction. In the beam profiler 42, a plurality of Faraday cups may be aligned in an array in the x-direction so that the beam currents can simultaneously be measured at a plurality of positions in the beam scanning direction (x-direction). The beam profiler 42 may be a measurement device that measures the beam current density distribution in the x-direction.

The beam profiler 42 may include a single Faraday cup for measuring the beam current, or may include an angle measurement device for measuring angle information of the beam. For example, the angle measurement device includes a slit and a plurality of current detectors provided away from the slit in the beam traveling direction (z-direction). For example, the angle measurement device can measure angle components of the beam in the slit width direction by causing the plurality of current detectors aligned in the slit width direction to measure the beam having passed through the slit. The beam profiler 42 may include a first angle measurement device capable of measuring the angle information in the x-direction and a second angle measurement device capable of measuring the angle information in the y-direction. The beam profiler 42 may be a measurement device that measures the beam angle in the x-direction and the beam angle in the y-direction. The beam profiler 42 may measure an angle center or a convergence/divergence angle, as the angle information of the beam.

The wafer holder 44 holds the wafer W at a position where the wafer W is irradiated with the ion beam when the ion implantation is performed. The wafer holder 44 is configured to move the wafer W in a direction (y-direction) perpendicular to the beam scanning direction (x-direction) when the ion implantation is performed. By moving the wafer W in the y-direction during the ion implantation, a whole processing target surface of the wafer W can be irradiated with the ion beam. The wafer holder 44 is also called a platen driving device including a mechanism for driving the wafer W in the y-direction.

The wafer accommodation unit 45 accommodates a wafer at a position which is not irradiated with the ion beam when the ion implantation is performed. The wafer accommodation unit 45 is configured to temporarily accommodate a plurality of wafers to which the same implantation condition is applied in the implantation processing chamber 40, for example. The implantation processing chamber 40 is provided with a wafer transfer mechanism (not illustrated) for transferring the wafer between the wafer holder 44 and the wafer accommodation unit 45. The wafer accommodation unit 45 may accommodate the wafer W subject to multiple implantation in which the same wafer is sequentially irradiated with a plurality of ion beams having mutually different beam energy. For example, the plurality of wafers are sequentially irradiated with a first ion beam having first energy, and the plurality of wafers irradiated with the first ion beam are accommodated in the wafer accommodation unit 45. Next, the plurality of wafers accommodated in the wafer accommodation unit 45 are sequentially fetched, and the fetched wafers are irradiated with a second ion beam having second energy. In this manner, it is possible to omit labor in unloading the plurality of wafers to the outside of the implantation processing chamber 40 and loading the plurality of wafers again from the outside of the implantation processing chamber 40 during the multiple implantation, and thus, productivity of the multiple implantation can be improved.

The substrate transfer device 46 is configured to transfer the wafer W between the load port 47 on which a wafer container 48 is mounted and the implantation processing chamber 40. The load port 47 is configured so that a plurality of the wafer containers 48 can be mounted at the same time, and for example, has four mounting tables aligned in the x-direction. A wafer container transfer port (not illustrated) is provided vertically above the load port 47, and is configured so that the wafer container 48 can pass through the wafer container transfer port in the vertical direction. For example, the wafer container 48 is automatically loaded onto the load port 47 through the wafer container transfer port by a transfer robot installed on a ceiling in a semiconductor manufacturing factory where the ion implanter 100 is installed, and is automatically unloaded from the load port 47.

The ion implanter 100 further includes a central control device 50. The central control device 50 controls an overall operation of the ion implanter 100. The central control device 50 is realized by an element or a machine device such as a computer CPU and a memory in terms of hardware, and is realized by a computer program or the like in terms of software. Various functions provided by the central control device 50 can be realized in cooperation between the hardware and the software.

An operation panel 49 having a display unit and an input device for setting the operation parameters of the ion implanter 100 is provided in the vicinity of the central control device 50. The positions of the operation panel 49 and the central control device 50 are not particularly limited. However, for example, the operation panel 49 and the central control device 50 can be disposed adjacent to an entrance/exit of the maintenance area MA between the beam generation unit 12 and the substrate transferring/processing unit 20. Work efficiency can be improved by adjoining locations of the ion source 10, the load port 47, the operation panel 49, and the central control device 50 which are frequently operated by an operator who manages the ion implanter 100.

The ion implanter 100 further includes an electrostatic acceleration/deceleration unit 52. The electrostatic acceleration/deceleration unit 52 is provided downstream of the beam acceleration unit 14. The electrostatic acceleration/deceleration unit 52 is configured to accelerate or decelerate the ion beam by using a potential difference between a first potential applied to a first casing 54 and a second potential applied to a second casing 56. In the example in FIG. 1, the electrostatic acceleration/deceleration unit 52 is provided between the beam parallelizer 36 and the final energy filter 38.

The first casing 54 is a casing including devices upstream of the electrostatic acceleration/deceleration unit 52. The first casing 54 includes the beam generation unit 12, the beam acceleration unit 14, the beam deflection unit 16, and parts (beam shaper 32, beam scanner 34, beam dump 35, and beam parallelizer 36) on the upstream side of the beam transport unit 18. The second casing 56 is a casing including devices downstream of the electrostatic acceleration/deceleration unit 52. The second casing 56 includes a part (final energy filter 38) on the downstream side of the beam transport unit 18 and the substrate transferring/processing unit 20. The first casing 54 and the second casing 56 are electrically insulated by an insulating structure 58.

The electrostatic acceleration/deceleration unite 52 has a DC power supply 60 that applies a DC voltage to at least one of the first casing 54 and the second casing 56. The DC power supply 60 generates the potential difference between the first casing 54 and the second casing 56, and causes the potential difference between the first casing 54 and the second casing 56 to be variable. In the example in FIG. 1, the DC power supply 60 is connected to the first casing 54, and generates the first potential applied to the first casing 54. In the example in FIG. 1, the second casing 56 is connected to the ground, and the second potential applied to the second casing 56 is a ground potential. In another example, the ground may be connected to the first casing 54, and the DC power supply 60 may be connected to the second casing 56. In still another example, a first DC power supply may be connected to the first casing 54, a second DC power supply may be connected to the second casing 56, and both the first potential and the second potential may be variable. As long as the potential difference is generated between the first casing 54 and the second casing 56, each of the first potential and the second potential may be set to be a positive, negative, or ground potential.

The electrostatic acceleration/deceleration unit 52 accelerates the ion beam passing through the electrostatic acceleration/deceleration unit 52 by setting the first potential to be a positive potential with reference to the second potential. For example, the second casing 56 is set to be the ground potential, and the first casing is set to be the positive potential. In this manner, the ion beam can be accelerated in a gap between the first casing 54 and the second casing 56. The electrostatic acceleration/deceleration unit 52 decelerates the ion beam passing through the electrostatic acceleration/deceleration unit 52 by setting the first potential to be a negative potential with reference to the second potential. For example, the second casing 56 is set to be the ground potential, and the first casing is set to be the negative potential. In this manner, the ion beam can be decelerated in the gap between the first casing 54 and the second casing 56.

An adjustment range of the beam energy adjusted by the electrostatic acceleration/deceleration unit 52 is determined by a product q·V of a charge state q of the ion and a voltage V which the DC power supply 60 can supply. For example, when the charge state of the ion is triply charged and a maximum acceleration voltage of the DC power supply 60 is 250 kV, the beam energy can be adjusted in a range of 0 to 750 keV. For example, when the charge state of the ion is triply charged and a maximum deceleration voltage of the DC power supply 60 is −250 kV, the beam energy can be adjusted in a range of 0 to −750 keV. The electrostatic acceleration/deceleration unit 52 can be used to supplementarily adjust the beam energy of the ion beam emitted from the beam acceleration unit 14. The adjustment range of the acceleration energy adjusted by the beam acceleration unit 14 is 0 to 10 MeV, for example.

The beam acceleration unit 14 has a large adjustment range of acceleration energy, and can also generate an ultra-high energy ion beam. However, in order to adjust the acceleration energy of the beam acceleration unit 14, it is necessary to individually adjust the operation parameters of the high frequency accelerators in a plurality of stages included in the beam acceleration unit 14, and it takes time to adjust the operation parameters depending on the number of stages. On the other hand, the adjustment range of the beam energy adjusted by the electrostatic acceleration/deceleration unit 52 is smaller than that adjusted by the beam acceleration unit 14. However, the beam energy can be adjusted only by changing the acceleration or deceleration voltage applied by the DC power supply 60. Accordingly, a time required for the adjustment is short. According to the present embodiment, the beam energy can easily be adjusted by combining the beam acceleration unit 14 and the electrostatic acceleration/deceleration unit 52 with each other. For example, the beam energy of the plurality of ion beams used for multiple implantation can more quickly adjusted.

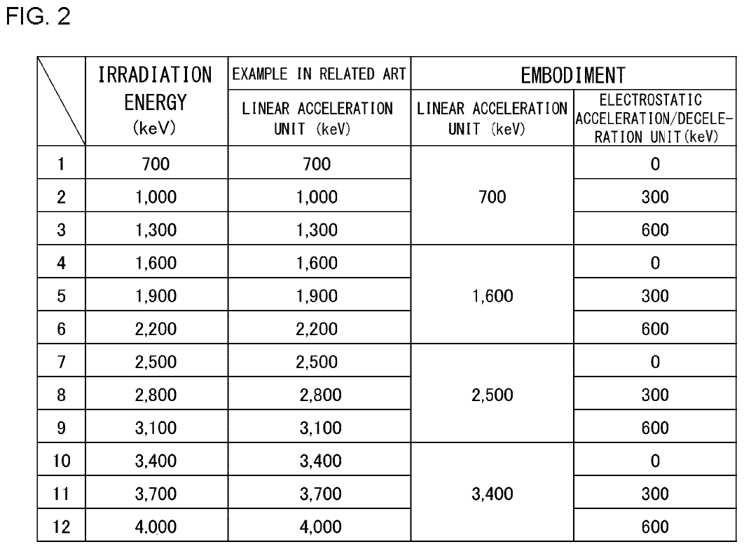

FIG. 2 is a view schematically illustrating an energy adjustment method for the plurality of ion beams having mutually different beam energy used for the multiple implantation. FIG. 2 illustrates a case where the beam energy of the ion beam with which the wafer W is irradiated is changed in a range of 700 keV to 4,000 keV at every interval of 300 keV so that 12 types of the ion beams are generated. In an example of the related art in which the electrostatic acceleration/deceleration unit 52 is not used, 12 types of the ion beams have to be generated by individually adjusting the operation parameters of the linear acceleration unit (beam acceleration unit 14). Accordingly, the operation parameters of the linear acceleration unit have to be adjusted 12 times. On the other hand, in the embodiment including the electrostatic acceleration/deceleration unit 52, the beam energy can be adjusted by using the electrostatic acceleration/deceleration unit 52. When the charge state of the ion beam is triply charged and the maximum voltage of the electrostatic acceleration/deceleration unit 52 is 250 kV, the beam energy can be adjusted in a range of 0 to 750 keV by the electrostatic acceleration/deceleration unit 52. Therefore, when the beam energy is adjusted in a range of 750 keV or lower, only the acceleration voltage of the electrostatic acceleration/deceleration unit 52 may be adjusted while the beam energy emitted from the linear acceleration unit is fixed. For example, while the beam energy of the ion beam emitted from the linear acceleration unit is fixed at 700 keV, the acceleration voltage of the electrostatic acceleration/deceleration unit 52 is set to be 0 kV, +100 kV, and +200 kV, and an energy adjustment amount adjusted by the electrostatic acceleration/deceleration unit 52 is set to be +0 keV, +300 keV, and +600 keV. In this manner, the ion beams having beam energy of 700 keV, 1,000 keV, and 1,300 keV can be generated. According to the present embodiment, even when 12 types of the ion beams are generated, the number of times for adjusting the operation parameters of the linear acceleration unit can be reduced to 4 times. FIG. 2 illustrates a case where the beam energy is adjusted by causing the electrostatic acceleration/deceleration unit 52 to accelerate the ion beam. However, the deceleration of the ion beam may be used by the electrostatic acceleration/deceleration unit 52. The acceleration and the deceleration of the ion beam may be used in combination by the electrostatic acceleration/deceleration unit 52.

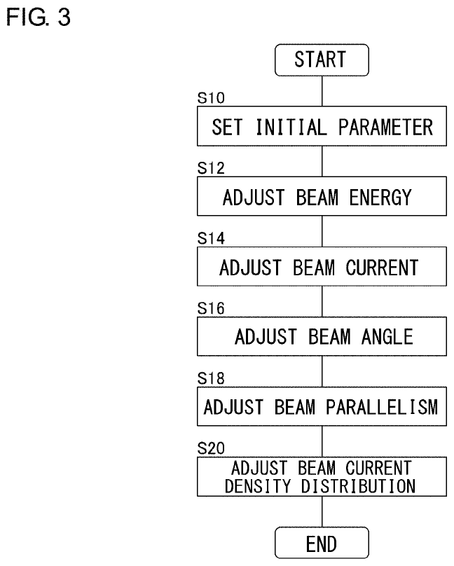

Subsequently, a flow of an adjustment process of the ion beam will be described. FIG. 3 is a flowchart illustrating an example of a first adjustment method for the ion beam. The first adjustment method is an adjustment method including adjustment of the operation parameters of the linear acceleration unit (beam acceleration unit 14). The flow illustrated in FIG. 3 is performed by an automatic adjustment program executed by the central control device 50. When a desired target value cannot be obtained by the adjustment using the automatic adjustment program, manual adjustment may be performed by the operator of the ion implanter 100.

First, initial values (also referred to as initial parameters) of the operation parameters of various devices are set (S10). Subsequently, a plurality of beam characteristics of the ion beam are adjusted (S12 to S20). In the example in FIG. 3, the beam energy (S12), the beam current (S14), the beam angle (S16), the beam parallelism(S18), and the beam current density distribution (S20) are adjusted in order. The order of adjustment in S12 to S20 is not limited, and the order of adjustment may be changed as appropriate. In addition, adjustment of a specific beam characteristic may be performed multiple times. For example, a second beam characteristic may be adjusted after a first beam characteristic is adjusted. Thereafter, the first beam characteristic may be adjusted again.

In S10, for example, the initial parameters corresponding to a target beam characteristic are determined. In S10, for example, the initial parameters are determined by a simulation using a predetermined algorithm. In S10, the initial parameters may be determined, based on a data set having an actually used result in the past. For example, when there is a past data set for which the ion beam having the beam characteristic that coincides with or approximates the target beam characteristic is obtained, a set values of the operation parameters included in the past data set may be used as the initial parameters.

In adjusting the beam energy in S12, the operation parameters of the beam generation unit 12 and the beam acceleration unit 14 are adjusted. Specifically, the beam energy is adjusted by changing the operation parameters such as an extraction voltage of the ion source 10, and an amplitude, a frequency, and a phase of a high frequency voltage VRF applied to each of the high frequency accelerators in the plurality of stages included in the beam acceleration unit 14. For example, the beam energy is measured by the beam measurement unit 23.

In adjusting the beam current in S14, the operation parameters of the beam generation unit 12, the beam acceleration unit 14, and the beam deflection unit 16 are changed. Specifically, the beam current is adjusted by changing the operation parameters such as a source gas flow rate, an arc current, an arc voltage, and a source magnet current of the ion source 10, and slit opening widths of the mass resolving slit 11b and the energy resolving slit 27. For example, the beam current is measured by the beam measurement unit 23, the first Faraday cup 28, the second Faraday cup 31, the beam monitor 41 or the beam profiler 42.

In adjusting the beam angle in S16, the operation parameters of the beam deflection unit 16 and the beam transport unit 18 are changed. For example, a center of the beam angle in the x-direction is adjusted by a magnet current of the bending electromagnet 30. The center of the beam angle in the y-direction is adjusted by an applied voltage of the final energy filter 38. Convergence/divergence angles in the x-direction and the y-direction are adjusted by applied voltages of the Q lenses included in the beam shaper 32. A beam size may be adjusted by changing the applied voltages of the Q lenses included in the beam shaper 32. For example, the beam angles and the beam size are measured by the beam monitor 41 or the beam profiler 42.

In adjusting the beam parallelism in S18, the operation parameters of the beam transport unit 18 are changed. Specifically, the beam parallelism is adjusted by changing applied voltages of the parallelizing lens electrodes included in the beam parallelizer 36. For example, the beam parallelism is measured by the beam monitor 41 or the beam profiler 42.

In adjusting the beam current density distribution in S20, the operation parameters of the beam transport unit 18 are changed. Specifically, the beam current density distribution in the x-direction is adjusted by changing a voltage waveform (scanning waveform) applied to the scanning electrode pair included in the beam scanner 34. For example, the beam current density distribution is measured by the beam monitor 41 or the beam profiler 42.

In the adjustment processes of S12 to S20, for example, the beam characteristic to be adjusted is measured, and at least one operation parameter is changed, based on a measurement value of the measured beam characteristic. When the measurement value of the beam characteristic satisfies a desired condition, the adjustment of the beam characteristic to be adjusted is completed. When the measurement value of the beam characteristic does not satisfy the desired condition, the at least one operation parameter is changed so that the beam characteristic satisfies the desired condition.

An adjustment process in the first adjustment method may be performed in a state where the ion beam is not accelerated and decelerated by the electrostatic acceleration/deceleration unit 52, or may be performed in a state where the ion beam is accelerated or decelerated by the electrostatic acceleration/deceleration unite 52.

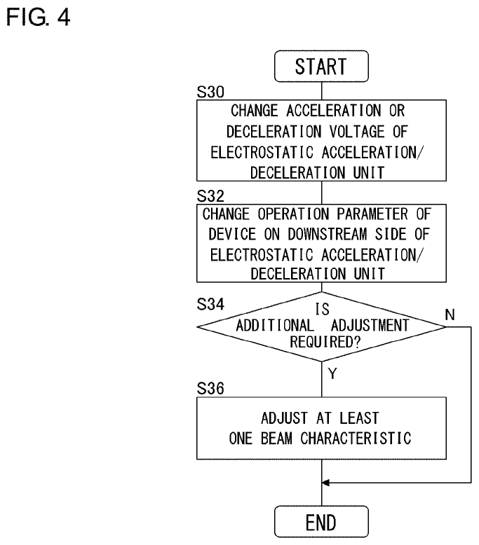

FIG. 4 is a flowchart illustrating an example of a second adjustment method for the ion beam. The second adjustment method is an adjustment method that does not include the adjustment of the operation parameters of the linear acceleration unit (beam acceleration unit 14). The flow illustrated in FIG. 4 is also performed by the automatic adjustment program executed by the central control device 50. When a desired target value cannot be obtained by the adjustment using the automatic adjustment program, manual adjustment may be performed by the operator of the ion implanter 100.

First, the acceleration or deceleration voltage of the electrostatic acceleration/deceleration unit 52 is changed (S30). The acceleration or deceleration voltage of the electrostatic acceleration/deceleration unit 52 may be changed in any desired way. For example, a state where the ion beam is not accelerated and decelerated by the electrostatic acceleration/deceleration unit 52 may be changed to a state where the ion beam is accelerated or decelerated by the electrostatic acceleration/deceleration unite 52. Specifically, the acceleration or deceleration voltage of the electrostatic acceleration/deceleration unit 52 may be changed from 0 kV to +100 kV (or −100 kV). Alternatively, a state where the ion beam is accelerated or decelerated by the electrostatic acceleration/deceleration unit 52 may be changed to a state where the ion beam is not accelerated and decelerated by the electrostatic acceleration/deceleration unit 52. Specifically, the acceleration or deceleration voltage of the electrostatic acceleration/deceleration unit 52 may be changed from +200 kV (or −200 kV) to 0 kV. In addition, a magnitude of the acceleration or deceleration voltage may be changed while a state where the ion beam is accelerated or decelerated by the electrostatic acceleration/deceleration unit 52 is maintained. Specifically, the acceleration or deceleration voltage of the electrostatic acceleration/deceleration unit 52 may be changed from +100 kV to +200 kV (or from −100 kV to −200 kV). Alternatively, a state where the ion beam is accelerated (or decelerated) by the electrostatic acceleration/deceleration unit 52 may be changed to a state where the ion beam is decelerated (or accelerated) by the electrostatic acceleration/deceleration unit 52. Specifically, the acceleration or deceleration voltage of the electrostatic acceleration/deceleration unit 52 may be changed from +100 kV to −200 kV (or from −100 kV to +200 kV).

Next, the operation parameters of the device downstream of the electrostatic acceleration/deceleration unit 52 is changed (S32). For example, in an apparatus configuration in FIG. 1, when the acceleration or deceleration voltage of the electrostatic acceleration/deceleration unit 52 is changed, it is necessary to change a target of the beam energy to pass through the final energy filter 38. Therefore, the operation parameters of the final energy filter 38 are changed so that the ion beam having the changed beam energy is directed toward the wafer W.

Subsequently, when additional adjustment is required (Y in S34), at least one of the beam characteristics is adjusted (S36). As the at least one of the beam characteristics, the beam current, the beam angle, the beam parallelism, or the beam current density distribution may be adjusted. When the beam current is adjusted, the slit width of the mass resolving slit 11b or the energy resolving slit 27 provided upstream of the electrostatic acceleration/deceleration unit 52 may be adjusted. When the beam current is adjusted, the slit width of the energy defining slit of the final energy filter 38 provided downstream of the electrostatic acceleration/deceleration unit 52 may be adjusted. When the beam angle, the beam parallelism, or the beam current density distribution is adjusted, adjustment the same as that in the processes in S16 to S20 in FIG. 3 may be performed. The beam quality can further be improved by performing the additional adjustment in S36.

When the additional adjustment is not required (N in S34), the process in S36 is skipped. In the second adjustment method, only the acceleration or deceleration energy is changed by the electrostatic acceleration/deceleration unit 52. Accordingly, there is only a small change in the beam characteristics other than the beam energy, such as the beam current, the beam angle, the beam parallelism, and the beam current density distribution. For example, when the beam characteristics are properly adjusted by the first adjustment method before the second adjustment method is performed, the beam characteristics equivalent to those before the change can be realized even after the acceleration or deceleration voltage of the electrostatic acceleration/deceleration unit 52 is changed. In this case, the process in S36 can be skipped. In this manner, while the beam quality is prevented from being degraded, the adjustment of the beam energy can quickly be completed.

According to the present embodiment, the beam energy of the ion beam with which the wafer W is irradiated can be adjusted in a wide range by changing the operation parameters of the beam acceleration unit 14 in the first adjustment method. As a result, the plurality of ion beams having different beam energy in a wide range (for example, 700 keV to 4000 keV) can be generated, and it is possible to realize multiple implantation in which the ions are implanted into a plurality of positions different in a depth direction.

According to the present embodiment, the beam energy of the ion beam with which the wafer W is irradiated can quickly be adjusted within a prescribed range by changing the acceleration or deceleration voltage of the electrostatic acceleration/deceleration unit 52 while all of the operation parameters of the beam acceleration unit 14 are fixed in the second adjustment method. As a result, it is possible to generate the plurality of ion beams having different beam energy at a small interval (for example, at an interval of 300 keV), and it is possible to easily realize the multiple implantation in which a highly accurately designed implantation profile can be formed in the depth direction.

According to the present embodiment, the first adjustment method and the second adjustment method are combined with each other. In this manner, even when the beam energy of the ion beam with which the wafer W is irradiated is adjusted at a small interval over a wide range, a time required for adjusting the beam energy can be shortened. As a result, it is possible to easily realize the multiple implantation in which the highly accurately designed implantation profile can be formed in an extremely deep range.

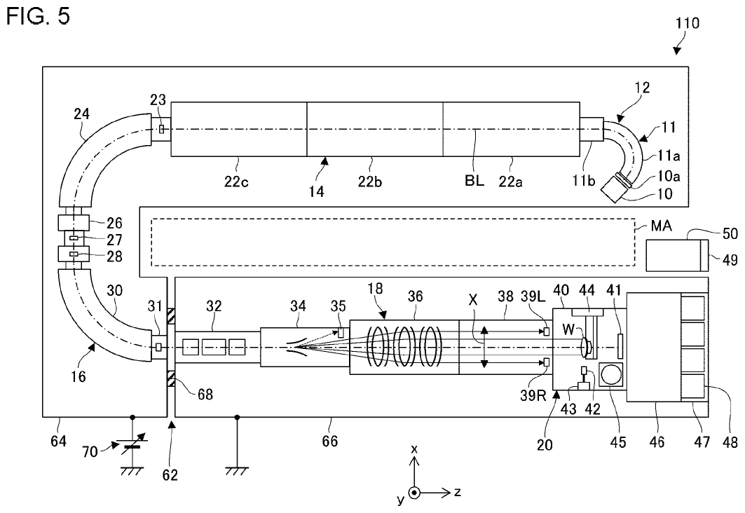

FIG. 5 is a top view illustrating a schematic configuration of an ion implanter 110 according to a modification example. As in the above-described embodiment, the ion implanter 110 includes the beam generation unit 12, the beam acceleration unit 14, the beam deflection unit 16, the beam transport unit 18, the substrate transferring/processing unit 20, and the central control device 50. In this modification example, a position of an electrostatic acceleration/deceleration unit 62 is different from that in the above-described embodiment, and the electrostatic acceleration/deceleration unit 62 is provided between the beam deflection unit 16 and the beam transport unit 18.

The electrostatic acceleration/deceleration unit 62 is configured to accelerate or decelerate the ion beam by using a potential difference between a first casing 64 and a second casing 66. The first casing 64 is a casing including devices upstream of the electrostatic acceleration/deceleration unit 62. The first casing 64 includes the beam generation unit 12, the beam acceleration unit 14, and the beam deflection unit 16. The second casing 66 is a casing including devices downstream of the electrostatic acceleration/deceleration unit 62. The second casing 66 includes the beam transport unit 18 and the substrate transferring/processing unit 20. The first casing 64 and the second casing 66 are electrically insulated by an insulating structure 68.

The electrostatic acceleration/deceleration unit 62 has a DC power supply 70 that applies a DC voltage to at least one of the first casing 64 and the second casing 66. The DC power supply 70 generates the potential difference between the first casing 64 and the second casing 66, and causes the potential difference between the first casing 64 and the second casing 66 to be variable.

In the example in FIG. 5, the DC power supply 70 is connected to the first casing 64, and generates a first potential applied to the first casing 64. In the example in FIG. 5, the second casing 66 is connected to the ground, and a second potential applied to the second casing 66 is the ground potential. In another example, the ground may be connected to the first casing 64, and the DC power supply 70 may be connected to the second casing 66. In still another example, a first DC power supply may be connected to the first casing 64, a second DC power supply may be connected to the second casing 66, and both the first potential and the second potential may be variable. As long as the potential difference is generated between the first casing 64 and the second casing 66, each of the first potential and the second potential may be set to be a positive, negative, or ground potential.

In this modification example, when the second adjustment method illustrated in FIG. 4 is performed, the operation parameters of the beam transport unit 18 located downstream of the electrostatic acceleration/deceleration unit 62 are adjusted in the process in S32. Specifically, the operation parameters of the beam shaper 32, the beam scanner 34, the beam parallelizer 36, and the final energy filter 38 are adjusted in accordance with the changed beam energy of the ion beam emitted from the electrostatic acceleration/deceleration unit 62.

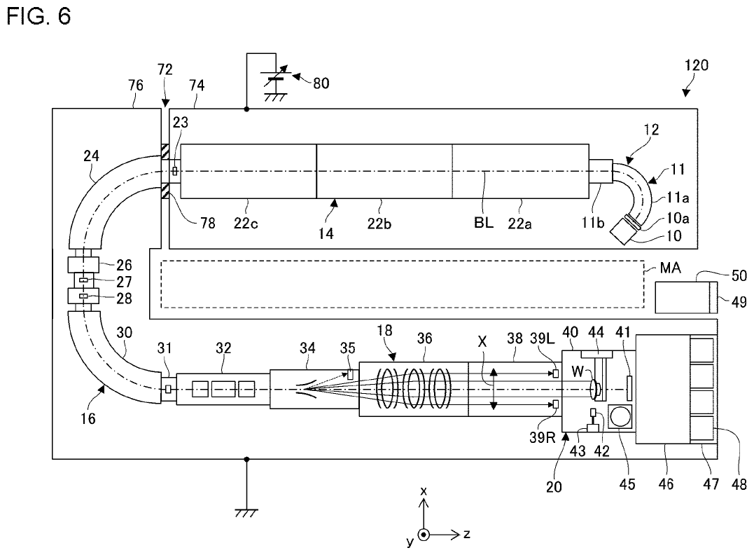

FIG. 6 is a top view illustrating a schematic configuration of an ion implanter 120 according to another modification example. As in the above-described embodiment, the ion implanter 120 includes the beam generation unit 12, the beam acceleration unit 14, the beam deflection unit 16, the beam transport unit 18, the substrate transferring/processing unit 20, and the central control device 50. In this modification example, a position of an electrostatic acceleration/deceleration unit 72 is different from that in the above-described embodiment, and the electrostatic acceleration/deceleration unit 72 is provided between the beam acceleration unit 14 and the beam deflection unit 16.

The electrostatic acceleration/deceleration unit 72 is configured to accelerate or decelerate the ion beam by using a potential difference between a first casing 74 and a second casing 76. The first casing 74 is a casing including devices upstream of the electrostatic acceleration/deceleration unit 72. The first casing 74 includes the beam generation unit 12 and the beam acceleration unit 14. The second casing 76 is a casing including devices downstream of the electrostatic acceleration/deceleration unit72. The second casing 76 includes the beam deflection unit 16, the beam transport unit 18, and the substrate transferring/processing unit 20. The first casing 74 and the second casing 76 are electrically insulated by an insulating structure 78.

The electrostatic acceleration/deceleration unit 72 has a DC power supply 80 that applies a DC voltage to at least one of the first casing 74 and the second casing 76. The DC power supply 80 generates the potential difference between the first casing 74 and the second casing 76, and causes the potential difference between the first casing 74 and the second casing 76 to be variable. In the example in FIG. 6, the DC power supply 80 is connected to the first casing 74, and generates a first potential applied to the first casing 74. In the example in FIG. 6, the second casing 76 is connected to the ground, and a second potential applied to the second casing 76 is the ground potential. In another example, the ground may be connected to the first casing 74, and the DC power supply 80 may be connected to the second casing 76. In still another example, a first DC power supply may be connected to the first casing 74, a second DC power supply may be connected to the second casing 76, and both the first potential and the second potential may be variable. As long as the potential difference is generated between the first casing 74 and the second casing 76, each of the first potential and the second potential may be set to be a positive, negative, or ground potential.

In this modification example, when the second adjustment method illustrated in FIG. 4 is performed, the operation parameters of the beam deflection unit 16 and the beam transport unit 18 which are located downstream of the electrostatic acceleration/deceleration unit 72 are adjusted in the process in S32. Specifically, the operation parameters of the energy analysis electromagnet 24, the horizontally focusing quadrupole lens 26, the bending electromagnet 30, the beam shaper 32, the beam scanner 34, the beam parallelizer 36, and the final energy filter 38 are adjusted in accordance with the changed beam energy of the ion beam emitted from the electrostatic acceleration/deceleration unit 72.

Hitherto, the present invention has been described with reference to the above-described respective embodiments. However, the present invention is not limited to the above-described respective embodiments. Those in which configurations of the respective embodiments are appropriately combined or replaced with each other are also included in the present invention. Based on the knowledge of those skilled in the art, the respective embodiments can be combined with each other, the processing sequences can be appropriately rearranged, or various modifications such as design changes can be added to the embodiment. The embodiment having the added modifications can also be included in the scope of the present invention.

It should be understood that the invention is not limited to the above-described embodiment, but may be modified into various forms on the basis of the spirit of the invention. Additionally, the modifications are included in the scope of the invention.

What is claimed is:

1. An ion implanter comprising:
an ion source that generates ions;
an extraction unit that generates an ion beam by extracting the ions from the ion source and accelerating the ions;
a linear acceleration unit that accelerates the ion beam extracted and accelerated by the extraction unit;
an electrostatic acceleration/deceleration unit that accelerates or decelerates the ion beam emitted from the linear acceleration unit; and
an implantation processing chamber in which implantation process is performed by irradiating a workpiece with the ion beam emitted from the electrostatic acceleration/deceleration unit.

2. The ion implanter according to claim 1,
wherein the electrostatic acceleration/deceleration unit accelerates or decelerates the ion beam by using a potential difference between a first potential applied to a first casing including the linear acceleration unit and a second potential applied to a second casing including the implantation processing chamber.

3. The ion implanter according to claim 1,
wherein the electrostatic acceleration/deceleration unit includes a DC power supply that applies a DC voltage to at least one of a first casing including the linear acceleration unit and a second casing including the implantation processing chamber.

4. The ion implanter according to claim 1, further comprising:
a control device that changes beam energy of the ion beam with which the workpiece is irradiated by changing an acceleration/deceleration voltage of the electrostatic acceleration/deceleration unit, while fixing all operation parameters of the linear acceleration unit.

5. The ion implanter according to claim 1,
wherein the implantation processing chamber includes a workpiece holding unit that holds the workpiece at a position where the workpiece is irradiated with the ion beam, a workpiece accommodation unit that accommodates the workpiece at a position where the workpiece is not irradiated with the ion beam, and a workpiece transfer mechanism that transfers the workpiece between the workpiece holding unit and the workpiece accommodation unit.

6. The ion implanter according to claim 1, further comprising:
a variable slit provided on an upstream side of the electrostatic acceleration/deceleration unit, and adjusting a beam current of the ion beam with which the workpiece is irradiated.

7. The ion implanter according to claim 1, further comprising:
a variable slit provided on a downstream side of the electrostatic acceleration/deceleration unit, and adjusting a beam current of the ion beam with which the workpiece is irradiated.

8. The ion implanter according to claim 1, further comprising:
a ribbon beam generator provided between the linear acceleration unit and the electrostatic acceleration/deceleration unit, and generating a ribbon beam by defocusing the ion beam in a direction perpendicular to a beam traveling direction, or generating a ribbon-like beam flux by performing a reciprocating scan using the ion beam in a direction perpendicular to the beam traveling direction.

9. The ion implanter according to claim 8, further comprising:
a beam parallelizer provided between the ribbon beam generator and the electrostatic acceleration/deceleration unit, and parallelizing a traveling direction of each ion forming the ribbon beam or a traveling direction of each beam forming the ribbon-like beam flux.

10. The ion implanter according to claim 1, further comprising:
an energy analyzer provided on a downstream side of the electrostatic acceleration/deceleration unit.

11. The ion implanter according to claim 1, further comprising:
a mass analyzer provided between the ion source and the linear acceleration unit.

12. An ion implantation method comprising: causing a linear acceleration unit to accelerate an ion beam;
causing an electrostatic acceleration/deceleration unit to accelerate or decelerate the ion beam emitted from the linear acceleration unit; and
irradiating a workpiece with the ion beam emitted from the electrostatic acceleration/deceleration unit.

13. The ion implantation method according to claim 12, further comprising:
changing beam energy of the ion beam with which the workpiece is irradiated by changing an acceleration/deceleration voltage of the electrostatic acceleration/deceleration unit, while fixing all operation parameters of the linear acceleration unit.

14. The ion implantation method according to claim 13,
wherein a plurality of the ion beams having mutually different beam energy are generated by changing the acceleration/deceleration voltage of the electrostatic acceleration/deceleration unit, while fixing all operation parameters of the linear acceleration unit, and multiple implantation process is performed by sequentially irradiating the workpiece with the plurality of ion beams.

15. The ion implantation method according to claim 12,
wherein a plurality of the ion beams having mutually different beam energy are generated by changing at least one operation parameter of the linear acceleration unit and an acceleration/deceleration voltage of the electrostatic acceleration/deceleration unit, and multiple implantation process is performed by sequentially irradiating the workpiece with the plurality of ion beams.

16. The ion implantation method according to claim 14,
wherein at least one of the plurality of ion beams is not accelerated and decelerated by the electrostatic acceleration/deceleration unit.

17. The ion implantation method according to claim 12, further comprising:
adjusting at least one beam characteristic of the ion beam; and
changing an acceleration/deceleration voltage of the electrostatic acceleration/deceleration unit after adjusting the at least one beam characteristic of the ion beam,
wherein without adjusting the at least one beam characteristic of the ion beam after changing the acceleration/deceleration voltage of the electrostatic acceleration/deceleration unit, the workpiece is irradiated with the ion beam emitted from the electrostatic acceleration/deceleration unit.

18. The ion implantation method according to claim 12, further comprising:
changing an acceleration/deceleration voltage of the electrostatic acceleration/deceleration unit; and
adjusting at least one beam characteristic of the ion beam after changing the acceleration/deceleration voltage of the electrostatic acceleration/deceleration unit,
wherein after adjusting the at least one beam characteristic of the ion beam, the workpiece is irradiated with the ion beam emitted from the electrostatic acceleration/deceleration unit.

19. The ion implantation method according to claim 17,
wherein the adjusting of at least one beam characteristic of the ion beam includes adjusting a beam current of the ion beam with which the workpiece is irradiated by changing a slit width of a variable slit provided on an upstream side or a downstream side of the electrostatic acceleration/deceleration unit.

20. The ion implantation method according to claim 17, further comprising:
causing a beam scanner provided between the linear acceleration unit and the electrostatic acceleration/deceleration unit to perform a reciprocating scan using the ion beam,
wherein the adjusting of at least one beam characteristic of the ion beam includes adjusting a beam current density distribution in a beam scan direction of the ion beam with which the workpiece is irradiated by changing a scan waveform for controlling an operation of the beam scanner.

21. The ion implantation method according to claim 12, further comprising:
sequentially irradiating a plurality of the workpieces with a first ion beam inside an implantation processing chamber;
accommodating the plurality of workpieces irradiated with the first ion beam in a workpiece accommodation unit provided inside the implantation processing chamber;
generating a second ion beam having beam energy different from that of the first ion beam by changing an acceleration/deceleration voltage of the electrostatic acceleration/deceleration unit; and
sequentially irradiating the plurality of workpieces accommodated in the workpiece accommodation unit with the second ion beam.
